(19) United States
(12) Patent Application Publication
(10) Pub. No.: US 2020/0049639 A1
(43) Pub. Date: Feb. 13, 2020

(54) Non-Invasive System for Determining Fluid Characteristics Within a Fluid Vessel and Methods Thereof

(71) Applicant: Cote Capital LLC, New York, NY (US)

(72) Inventors: Stephen Quirk, Alpharetta, GA (US); Joseph R. Feldkamp, Appleton, WI (US)

(21) Appl. No.: 16/492,671

(22) PCT Filed: Mar. 10, 2017
(86) PCT No.: PCT/US17/21702

§ 371 Date: Sep. 10, 2019

(51) Int. Cl. G01N 27/02; G01N 27/06

(52) U.S. Cl. CPC G01N 27/023; G01R 27/267; G01N 27/06

(57) ABSTRACT

Non-invasive systems for and methods of determining fluid characteristics within a fluid vessel are disclosed. The methods can include providing a sensor system comprising a single coil magnetic induction conductivity sensor, a processor, and a computing system configured to run an analytical coil-loss model. The method can include calibrating the sensor system to the vessel to provide a column calibration factor. The column calibration factor is dependent upon a cross-sectional area of the vessel and a wall thickness of the vessel. The single coil magnetic induction conductivity sensor can be placed near an external surface of the vessel at a portion of the vessel that is non-conductive. The method can include generating a coil loss measurement utilizing the single coil magnetic induction conductivity sensor and converting the coil loss measurement to a conductivity value of the fluid within the vessel.

### TECHNICAL FIELD

The present disclosure relates generally to systems for and methods of determining fluid characteristics within fluid vessels.

### BACKGROUND OF THE DISCLOSURE

Measuring fluid characteristics within a fluid vessel is applicable to a wide variety of industries. For example, measuring conductivity of a solution is a fluid characteristic that can be useful in desalination, protein purification, dialysis, among others. Traditional systems of measuring conductivity of solutions in non-conductive vessels involve invasive techniques that place a conductivity cell directly into the fluid stream through the fluid vessel wall. Such practices can present concerns due to disrupting fluid flow, such as when the fluids within the vessel are corrosive, radioactive, environmentally sensitive, or contain labile solutes. Additionally, invasive methods also create opportunities for leaks in the vessel and other maintenance tasks, increasing potential resource time and/or costs.

While non-invasive systems of measuring conductivity within a fluid vessel have been created, such systems are complex and costly. For example, these systems contain multiple electrodes or coils for measuring characteristics of the fluid within the fluid vessel. Furthermore, these systems are, for practical purposes, stationary in nature in that once they are implemented at a particular monitoring location, considerable time and resources must be undertaken to move the systems to a different monitoring location on the fluid vessel. An alternative would be to install multiple monitoring systems, however, doing so would create additional expense.

As such, there remains a need for non-invasive systems and methods of determining fluid characteristics within a fluid vessel that are less complex. There also remains a need for non-invasive systems and methods of determining fluid characteristics within a fluid vessel that provide increased mobility for the locations in which the fluid characteristics can be measured.

### SUMMARY OF THE DISCLOSURE

The present discloses comprises systems and methods of determining fluid characteristics within vessels that may satisfy one or more of the foregoing needs.

Accordingly, in one aspect, a non-invasive method of determining a fluid characteristic within a vessel is provided. The vessel can includes at least a portion that is non-conductive. The method can include providing a sensor system. The sensor system can include a single coil magnetic induction conductivity sensor, a processor, and a computing system. The processor and the computing system can be configured to run an analytical coil-loss model. The method can further include calibrating the sensor system to the vessel to provide a column calibration factor in the analytical coil-loss model. The column calibration factor can be dependent upon a cross-sectional area of the vessel and a wall thickness of the vessel. The method can also include positioning the single coil magnetic induction conductivity sensor near an external surface of the vessel at the at least a portion of the vessel that is non-conductive. The method can additionally include generating a coil loss measurement utilizing the single coil magnetic induction conductivity sensor. Furthermore, the method can include converting the coil loss measurement to a conductivity value of the fluid within the vessel.

In another aspect, a non-invasive method of determining a presence and a location of an obstruction to fluid flow within a vessel is provided. The vessel can include at least a portion that is non-conductive. The method can include providing a sensor system. The sensor system can include a single coil magnetic induction conductivity sensor, a processor, and a computing system. The processor and the computing system can be configured to run an analytical coil-loss model. The method can further include positioning the single coil magnetic induction conductivity sensor near an external surface of the vessel at the at least a portion of the vessel that is non-conductive. The method can additionally include moving the single coil magnetic induction conductivity sensor with respect to the vessel. The method can also include generating a plurality of coil loss measurements utilizing the single coil magnetic induction conductivity sensor. The method can include analyzing the plurality of coil loss measurements. In addition, the method can include determining the presence and the location of the obstruction in the vessel due to a substantial change in a progression of the plurality of coil loss measurements.

In yet another aspect, a non-invasive method of determining a fluid conductivity gradient within a vessel is disclosed. The vessel can include at least a portion that is non-conductive. The method can include providing a sensor system. The sensor system can include a single coil magnetic induction conductivity sensor, a processor, and a computing system. The processor and the computing system can be configured to run an analytical coil-loss model. The method can include calibrating the sensor system to the vessel to provide a column calibration factor in the analytical coil-loss model. The column calibration factor can be dependent upon a cross-sectional area of the vessel and a wall thickness of the vessel. The method can also include positioning the single coil magnetic induction conductivity sensor near an external surface of the vessel at the at least a portion of the vessel that is non-conductive. Furthermore, the method can include generating a plurality of coil loss measurements utilizing the single coil magnetic induction conductivity sensor as the fluid flows within the vessel. The method can additionally include converting the plurality of coil loss measurements to a plurality of conductivity values of the fluid within the non-conductive vessel to determine the fluid conductivity gradient within the vessel.

In still another aspect, a non-invasive system configured for determining a fluid characteristic within a fluid in a vessel is provided. The system can include a coil device. The coil device can include a single coil configured to be energized to induce an eddy current. The coil device can also include a processor configured to determine a plurality of coil loss measurements in the single coil. The coil device can further include a computing system configured for receiving the plurality of coil loss measurements. The computing system can include a processor, a memory device, and a magnetic induction conductivity sensor module. The magnetic induction conductivity sensor module can be configured to implement an analytical coil-loss model. The analytical coil loss model can be calibrated to provide a column calibration factor. The column calibration factor can be dependent upon a cross-sectional area of the vessel and a wall thickness of the vessel. The analytical coil-loss model can be configured to define a relationship between the plurality of coil loss measurements obtained by the single coil and a fluid conductivity based on the column calibration factor.

### BRIEF DESCRIPTION OF DRAWINGS

FIG. 1 illustrates an exemplary system for non-invasive method of measuring a fluid characteristic within a fluid vessel including depicting a sensor system comprising a single coil magnetic induction conductivity sensor.

FIG. 2 illustrates a perspective view of an exemplary hand held device of an exemplary embodiment of a sensor system depicted in FIG. 1.

FIG. 3 illustrates a side view of the exemplary hand held device of FIG. 2.

FIG. 4 illustrates an exemplary coil for conductivity sensing according to exemplary embodiments of the present disclosure.

FIG. 5 illustrates exemplary connection traces for a coil for conductivity sensing according to exemplary embodiments of the present disclosure.

FIG. 6 illustrates a block diagram of an exemplary circuit associated with a coil used for conductivity sensing according to exemplary embodiments of the present disclosure.

FIG. 7 illustrates a cross-sectional, front plan view of a coil device positioned near a fluid vessel including a fluid.

FIG. 8 illustrates a cross-sectional view taken along line 8-8 in FIG. 7.

FIG. 9A illustrates a graph of actual conductivity of fluid and measured coil loss in a 2.5 cm diameter vessel.

FIG. 9B illustrates a graph of actual conductivity of fluid and measured coil loss in a 5.0 cm diameter vessel.

FIG. 9C illustrates a graph of actual conductivity of fluid and measured coil loss in a 4.0 cm diameter vessel.

FIG. 10 illustrates a graph of a linear fluid conductivity gradient by depicting measured coil loss and volume of fluid moving in relation to an exemplary sensor system as described herein.

FIG. 11 illustrates a graph of another linear fluid conductivity gradient by depicting measured coil loss and volume of fluid moving in relation to an exemplary sensor system as described herein.

FIG. 12 illustrates a graph of a concave fluid conductivity gradient by depicting measured coil loss and volume of fluid moving in relation to an exemplary sensor system as described herein.

FIG. 13 illustrates a graph depicting detection of a change in fluid conductivity in a fluid within a vessel moving in relation to an exemplary sensor system as described herein.

FIG. 14 illustrates a graph depicting detection of a change in fluid conductivity in a fluid within a vessel moving in relation to an exemplary sensor system as described herein.

FIG. 15 illustrates a cross-sectional front plan view of a coil device positioned near a fluid vessel including a fluid and capable of moving with respect to the fluid vessel.

FIG. 16 illustrates a graph depicting detection of a variance in fluid characteristics of a fluid within a vessel moving in relation to an exemplary sensor system as described herein.

FIG. 17 illustrates a graph depicting detection of a variance in fluid characteristics of a fluid within a vessel moving in relation to an exemplary sensor system as described herein.

FIG. 18 illustrates a graph depicting detection of a variance in fluid characteristics of a fluid within a vessel moving in relation to an exemplary sensor system as described herein.

FIG. 19 illustrates a perspective view of an alternative embodiment of a coil device positioned near a fluid vessel including a fluid.

Repeat use of reference characters in the present specification and drawings is intended to represent the same or analogous features or elements of the disclosure.

### DETAILED DESCRIPTION OF THE DISCLOSURE

Reference now will be made in detail to embodiments, one or more examples of which are illustrated in the drawings. Each example is provided by way of explanation of the embodiments, not limitation of the invention. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

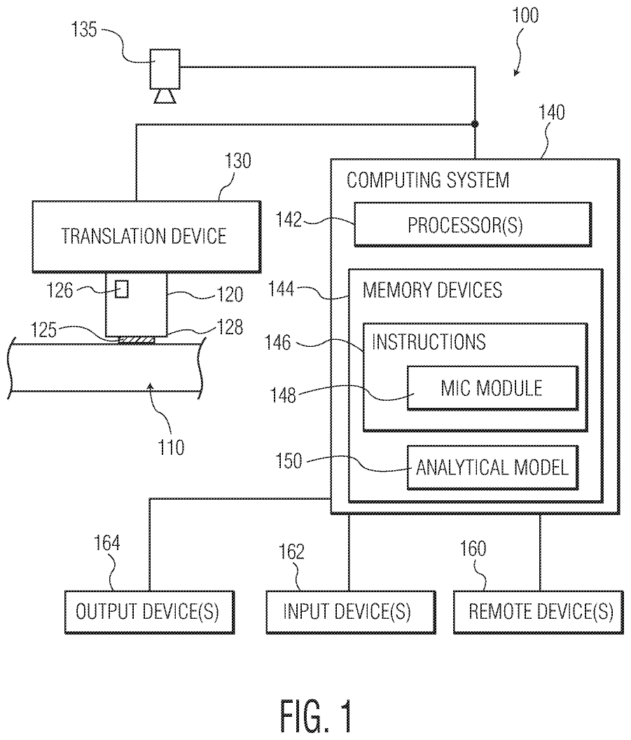

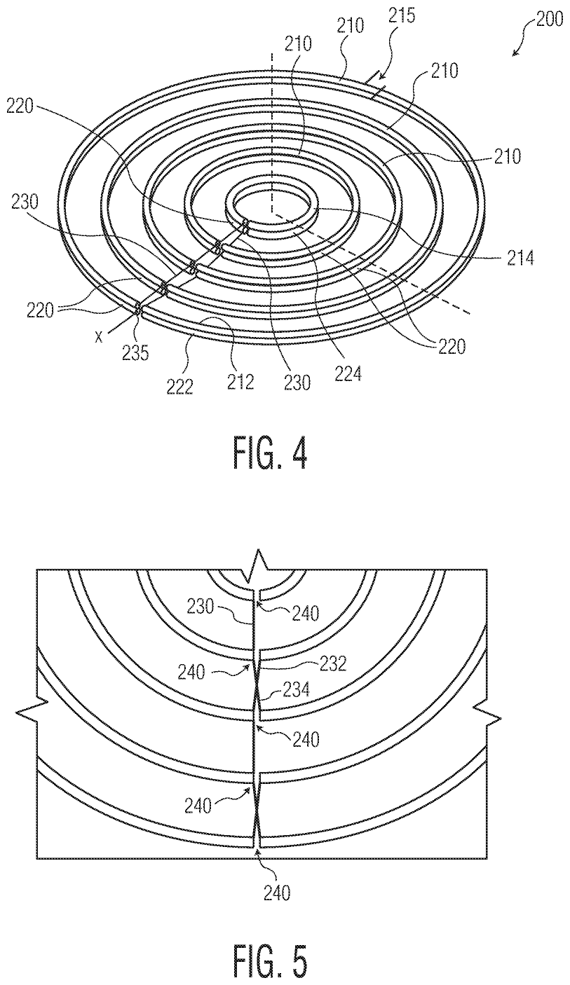

FIGS. 1-6 illustrate an exemplary sensor system 100 and various components of the system 100 that can be configured for non-invasively measuring fluid characteristics of a fluid 112 within a vessel 110. As such, the sensor system 100 as described herein can be utilized in methods of non-invasively measuring fluid characteristics within a vessel 110. The system 100 includes a coil device 120 having a single coil 125 for obtaining coil property measurements for conductivity sensing according to example aspects of the present disclosure. The coil 125 can be a single coil having a plurality of concentric conductive loops disposed in one or more planes on a printed circuit board. One exemplary coil design for conductivity sensing according to exemplary aspects of the present disclosure will be discussed in more detail below with reference to FIGS. 4 and 5 below.

The coil device 120 of FIG. 1 can include an RF energy source (e.g. an oscillator circuit) configured to energize the coil 125 with RF energy at a set frequency (e.g. 12.5 MHz) when the coil 125 is placed adjacent to the vessel 110. The energized coil 125 can generate magnetic fields, which can induce eddy currents through fluid and other contents contained within the vessel, as will be discussed in further detail below. These induced eddy currents in the fluid and other contents within the vessel 110 can cause a coil loss (e.g. a change in impedance) of the coil 125. The coil device 120 can include circuitry (e.g. a measurement circuit) for determining the coil loss associated with the coil 125 during a coil property measurement at a particular location relative to the vessel 110.

Coil property measurements can be obtained using the single coil 125 of the coil device 120 while the coil device 120 is positioned at a variety of different locations and orientations relative to the vessel 110, or the coil device 120 can be held or fixed in a stationary position with respect to the vessel 110 and coil property measurements can be obtained as fluid flows within the vessel 110. The collected coil property measurements can be provided to the computing system 140 where the coil property measurements can be analyzed and converted to conductivity measurements for the fluid or contents within the vessel 110, as will be discussed in further detail below.

The coil device 120 can be manually positioned at the plurality of discrete locations for performance of the coil property measurement. For instance, an operator can manually position a hand held coil device 120 relative to the vessel 110 and move the coil device 120 with respect to the vessel 110 to obtain coil property measurements at a plurality of discrete locations relative to the specimen 110.

Alternatively, in some implementations, the coil device 120 can be mounted to a translation device 130. The translation device 130 can be a robotic device controlled, for instance, by the computing system 140 or other suitable control device, to translate the coil device 120 along x-, y-, and −z axes relative to the vessel 110 in order to position the coil 125 at a plurality of different discrete locations relative to the vessel 110. The coil device 120 can be controlled (e.g. by the computing system 140) to obtain a coil property measurement using the coil 125 at each of the plurality of discrete locations.

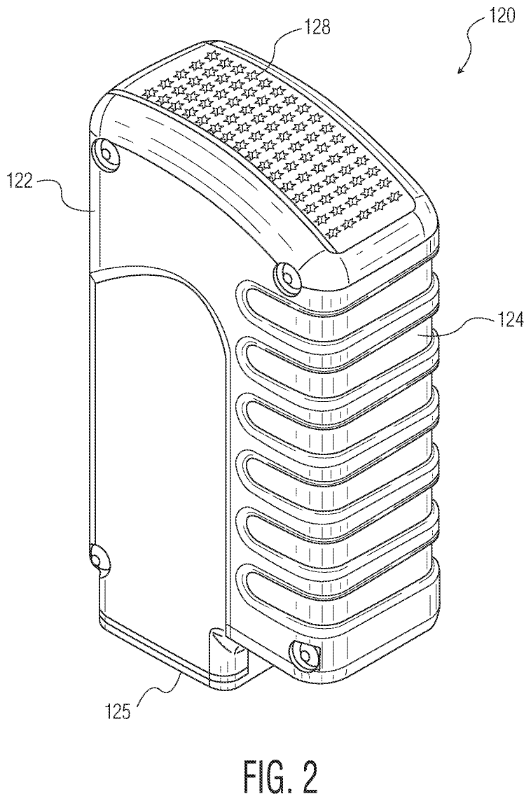

FIG. 2 depicts a perspective view on one example embodiment of a hand held device 120 according to example embodiments of the present disclosure. As shown, the hand held device 120 includes a housing 122 for storing and protecting various components (e.g., electrical components) of the hand held device 120 used to support acquisition of coil measurements using sensing unit 125.

The example hand held device 120 of FIG. 2 includes a form factor to facilitate holding the hand held device 120 by hand during acquisition of coil measurements. For instance, the hand held device 120 includes a grip portion 124. As illustrated in FIG. 2, the grip portion 124 can include one or more grooves or channels to facilitate grasping or holding the hand held device by hand 120. The hand held device 120 further includes a form factor such that the location of a hand grasping the housing when in operation is separated a threshold distance from the single coil of the sensing unit 125. For instance, the grip portion 124 can be located in the range of about 0.5 inches to about 6 inches away from the sensing unit 125, such as about 2 inches to 4 inches away from the sensing unit, such as about 3 inches away from the sensing unit. In this way, interference between a technician's hand and the sensing unit 125 can be reduced while performing measurements with the hand held device 120.

The hand held device 120 depicts one example form factor according to example embodiments of the present disclosure to facilitate holding the device by hand. Those of ordinary skill in the art, using the disclosures provided herein, should understand that other form factors are contemplated. For instance, the hand held device 120 can have a housing having a first portion that has a first shape adapted to conform to the sensing unit 125 and a second portion that is a different shape (e.g., a cylindrical shape) that is adapted to be held by hand during operation.

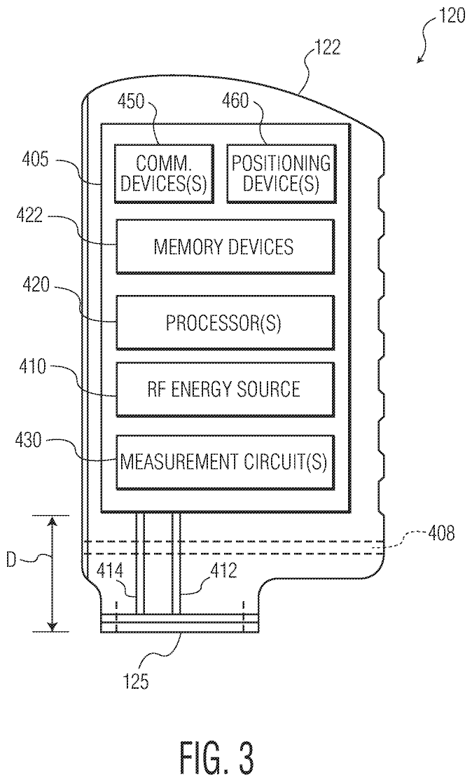

As shown in FIG. 3, the hand held device 120 can include one or more electrical components to support operation of the hand held device 120. The one or more electrical components can include a power source such as a battery (not shown), an RF energy source 410, processor(s) 420, memory device(s) 422, measurement circuit(s) 430, communication device(s) 450, and positioning device(s) 460.

Referring to FIG. 3, the RF energy source 410 (e.g., an oscillator circuit) can be configured to generate RF energy for energizing the coil of the sensing unit 125. The processor(s) 420 can be configured to control various aspects of the circuit 400 as well as to process information obtained by the circuit 400 (e.g., information obtained by measurement circuit 430). The processor(s) 420 can include any suitable processing device, such as digital signal processor, microprocessor, microcontroller, integrated circuit or other suitable processing device. The memory devices 422 can be configured to store information and data collected by the hand held device 120. For instance, the memory devices 422 can be configured to store coil measurements obtained by the sensing unit 125. The memory devices 422 can include single or multiple portions of one or more varieties of tangible, non-transitory computer-readable media, including, but not limited to, RAM, ROM, hard drives, flash drives, optical media, magnetic media or other memory devices. The measurement circuit 430 can be configured to obtain coil measurements of the single coil of the sensing unit 125.

The positioning device(s) 460 of FIG. 3 can include circuitry for supporting one or more sensors used to determine the position and/or orientation of the hand held device 120 when performing coil measurements. For instance, the positioning device(s) 460 can include motion sensors (e.g., accelerometers, compass, magnetometers, gyroscopes, etc.) and other suitable sensors that provide signals indicative of the orientation of the hand held device 120. Further, the hand held device 120 can include depth sensors (e.g., laser sensors, infrared sensors, image capture devices) that can be used to determine a depth or distance of the hand held device 120 to a specimen. Signals from the positioning device(s) 460 can be used in determining a position and/or orientation associated with each coil measurement. The position data can be indicative of the position (e.g. as defined by an x-axis, y-axis, and a z-axis relative to the vessel 110) of the coil 125 as well as an orientation of the coil 125 (e.g. a tilt angle relative to the vessel 110). When using a translation device 130 to position the coil 125, the position and orientation of the coil 125 can be determined based at least in part on positioning control commands that control the translation device 130 to be positioned at the plurality of discrete locations.

The communication device(s) 450 can be used to communicate information from the hand held device 120 to a remote location, such as a remote computing device. The communication device(s) can include, for instance, transmitters, receivers, ports, controllers, antennas, or other suitable components for communicating information from the hand held device 120 over a wired and/or wireless network.

The various electrical components supporting operation of the hand held device 120 can be disposed on a printed circuit board 405 within the housing 122 of the hand held device 120. As illustrated, in FIG. 3, the one or more electrical components can be separated a threshold distance D from the sensing unit 125 so as to reduce interference between the one or more electrical components and the sensing unit 125. In particular embodiments, the threshold distance D can be in the range of about 0.5 inches to about 4 inches, such as about 2 inches to 3 inches away, such as about 2 inches.

As shown in FIG. 3, the hand held device 120 can further include a shield 408. The shield 408 can be manufactured from a conductive material or high dielectric constant, non-lossy material. The shield 408 can separate the sensing unit 125 from the electrical components supporting operation of the hand held device 120 to further reduce electromagnetic interference between the electrical components and the sensing unit 125. Conductive paths 412 and 414 passing through the shield 408 can be used to communicate signals from the sensing unit 125 to the electrical components supporting operation of the hand held device 120. One or more of the electrical components supporting operation of the hand held device and other components of the magnetic induction system for conductivity measurements can be located at a location remote from the hand held device 120.

In one embodiment of the present disclosure, images captured by a camera 135 positioned above the specimen 110 and the coil device 120 can be processed in conjunction with signals from various sensors associated with the coil device 120 to determine the position data for each coil property measurement. More particularly, the coil device 120 can include one or more motion sensors 126 (e.g. a three-axis accelerometer, gyroscope, and/or other motion sensors) and a depth sensor 128 The orientation of the single coil 125 relative to the surface can be determined using the signals from the motion sensors 126. For instance, signals from a three-axis accelerometer can be used to determine the orientation of the single coil 125 during a coil property measurement.

The depth sensor 128 can be used to determine the distance from the single coil to the vessel 110. The depth sensor 128 can include one or more devices configured to determine the location of the coil 125 relative to a surface. For instance, the depth sensor 128 can include one or more laser sensor devices and/or acoustic location sensors. In another implementation, the depth sensor 128 can include one or more cameras configured to capture images of the specimen 110. The images can be processed to determine depth to the specimen 110 using, for instance, structure-from-motion techniques.

Images captured by the camera 135 can be used to determine the position of the coil 125 along an x-axis and y-axis. More particularly, the coil device 120 can also include a graphic located on a surface of the coil device 120. As the plurality of coil property measurements are performed, the image capture device 135 can capture images of the graphic. The images can be provided to the computing system 140, which can process the images based on the location of the graphic to determine the position along the x-axis and y-axis relative to the vessel 110. In particular implementations, the camera 135 can include a telecentric lens to reduce error resulting from parallax effects.

In some embodiments, the magnetic induction conductivity device can include one or more reflective components mechanically coupled to the device. The reflective components can be, for instance, a plurality of reflective spheres or other reflective bodies (e.g., cubes, cylinders, trapezoids, etc.). An optical tracking sensor located proximate to an area where the hand held magnetic induction conductivity device is in use can generate signals indicative of the location of one or more reflective components based on a reflection of optical signals (e.g., infrared signals or other optical signals) from the plurality of reflective spheres.

The computing system 140 can receive the coil property measurements, together with coil location and orientation data, and can process the data as will be further described below to convert the coil loss measurements to conductivity values of the fluid within the vessel 110. The computing system 140 can include one or more computing devices, such as one or more of a desktop, laptop, server, mobile device, display with one or more processors, or other suitable computing device having one or more processors and one or more memory devices. The computing system 140 can be implemented using one or more networked computers (e.g., in a cluster or other distributed computing system). For instance, the computing system 140 can be in communication with one or more remote devices 160 (e.g. over a wired or wireless connection or network).

The computing system 140 includes one or more processors 142 and one or more memory devices 144. The one or more processors 142 can include any suitable processing device, such as a microprocessor, microcontroller, integrated circuit or other suitable processing device. The memory devices 144 can include single or multiple portions of one or more varieties of tangible, non-transitory computer-readable media, including, but not limited to, RAM, ROM, hard drives, flash drives, optical media, magnetic media or other memory devices. The computing system 140 can further include one or more input devices 162 (e.g. keyboard, mouse, touchscreen, touchpad, microphone, etc.) and one or more output devices 164 (e.g. display, speakers, etc.). In one exemplary set-up, the computing system 140 can include an alarm (not labeled) that can provide an alert for a condition measured by the sensor system 100. The alert can be auditory, visual, tactile, or in some other form to alert an operator or individual of a condition measured by the sensor system. In an example further described below, the computing system can comprise an alarm that is configured to provide an alert for an obstruction 118 in the fluid 112 in a vessel 110.

The memory devices 144 can store instructions 146 that when executed by the one or more processors 142 cause the one or more processors 142 to perform operations. The computing device 140 can be adapted to function as a special-purpose machine providing desired functionality by accessing the instructions 146. The instructions 146 can be implemented in hardware or in software. When software is used, any suitable programming, scripting, or other type of language or combinations of languages may be used to implement the teachings contained herein.

As illustrated, the memory devices 144 can store instructions 146 that when executed by the one or more processors 142 cause the one or more processors 142 to implement a magnetic induction conductivity (“MIC”) module 148. The MIC module 148 can be configured to implement one or more of the methods disclosed herein for conductivity sensing using a single coil, including converting the coil property measurements to generate conductivity values of the fluid within the vessel 110.

The one or more memory devices 144 of FIG. 1 can also store data, such as coil property measurements, position data, fluid conductivity data, and other data. As shown, the one or more memory devices 144 can store data associated with an analytical coil-loss model 150. The analytical coil-loss model 150 can define a relationship between coil property measurements obtained by a single coil 125 and fluid conductivity values within the vessel 110. Features of an example analytical coil-loss model 150 will be discussed in more detail below.

MIC module 148 may be configured to receive input data from input device 162, from coil device 120, from translation device 130, from data that is stored in the one or more memory devices 144, or other sources. The MIC module 148 can then analyze such data in accordance with the disclosed methods, and provide useable output such as fluid conductivity values to a user via output device 164. Analysis may alternatively be implemented by one or more remote device(s) 160.

The technology discussed herein makes reference to computing systems, servers, databases, software applications, and other computer-based systems, as well as actions taken and information sent to and from such systems. One of ordinary skill in the art, using the disclosures provided herein, will recognize that the inherent flexibility of computer-based systems allows for a great variety of possible configurations, combinations, and divisions of tasks and functionality between and among components. For instance, processes discussed herein may be implemented using a single computing device or multiple computing devices working in combination. Databases and applications may be implemented on a single system or distributed across multiple systems. Distributed components may operate sequentially or in parallel.

Exemplary Quantitative Analytical Coil-Loss Model for a Single Coil

An exemplary quantitative analytical coil-loss model for obtaining fluid conductivity values from a plurality of coil property measurements obtained by a magnetic induction conductivity device will now be set forth. The quantitative coil-loss model is developed for an arbitrary conductivity distribution, but with permittivity and magnetic permeability treated as spatially uniform. The quantitative analytical coil-loss model was developed for a coil geometry that includes a plurality of concentric circular loops, all lying within a common plane and connected in series, with the transient current considered to have the same value at all points along the loops. A conductivity distribution is permitted to vary arbitrarily in space while a solution for the electric field is pursued with a limit of small conductivity (<10 S/m). Charge free conditions are assumed to hold, whereby the electrical field is considered to have zero divergence. Under these conditions, fields are due only to external and eddy currents.

The quantitative analytical coil-loss model can correlate a change in the real part of impedance (e.g., ohmic loss) of the coil with various parameters, including the conductivity distribution of the fluid or other contents within the vessel 110, the position and orientation of the single coil relative to the vessel 110, coil geometry (e.g. the radius of each of the plurality of concentric conductive loops) and other parameters. One example coil-loss model is provided below:

$$- δ {Z}_{re} = \frac{{μ}^{2} {ω}^{2}}{4 {π}^{2}} {\sum }_{j , k} \sqrt{{ρ}_{j} {ρ}_{k}} \int {d}^{3} x \frac{\breve{σ} ( \vec{r} )}{ρ} {Q}_{\frac{1}{2}} ( {η}_{j} ) {Q}_{\frac{1}{2}} ( {η}_{k} )$$

−δZre is the coil property measurement (e.g., the real part of the impedance loss of the coil). μ is the magnetic permeability in free space. ω is the excitation frequency of the coil. ρk and ρj are the radii of each conductive loop j and k for each interacting loop pair j,k. The function Q½ is known as a ring function or toroidal harmonic function, which has the argument ηj and ηk as shown here:

$${η}_{j} = \frac{{ρ}^{2} + {ρ}_{j}^{2} + {z}^{2}}{2 {ρρ}_{j}}$$

$${η}_{k} = \frac{{ρ}^{2} + {ρ}_{k}^{2} + {z}^{2}}{2 {ρρ}_{k}}$$

With reference to a coordinate system placed at the center of the concentric loops, such that loops all lie within the XY-plane, ρ measures radial distance from coil axis to a point within the specimen while z measures distance from the coil plane to the same point within the specimen.

The coil-loss model introduces electrical conductivity \check{σ}(\vec{r}) as a function of position. The integrals can be evaluated using a finite element mesh to generate the conductivity distribution for a plurality of coil property measurements as will be discussed in more detail below.

The coil-loss model relating a coil loss measurement at a particular coil position and orientation to an entire electrical conductivity distribution is actually a 3D convolution model. This can be seen from recasting the model into the a frame defined by a coil center—with the coil's Z-axis perpendicular to the coil plane, while the coil's X-axis and Y-axis lie within the coil plane. Letting the vector c locate the coil center relative to the lab frame origin, and the vector \vec{r_{c}} locate the field point in the coordinate system (CS) of the coil, a revised form for the model is as follows:

Z(\vec{c})=∫σₗ(\vec{c}+\tilde{R}\vec{r}_{c})G(\vec{r}_{c})dx_{c}dy_{c}dz_{c}=∫σₗ(\vec{r})G(\tilde{R}^{T}(\vec{r}−\vec{c})dxdydz

In the above, the function G(\vec{r_{c}}) is recognized as the kernel of the convolution integral and can be defined as follows:

$$G ( {\vec{r}}_{c} ) = \frac{{μ}^{2} {ω}^{2}}{4 {π}^{2}} \frac{1}{ρ} {\sum }_{j , k} \sqrt{{ρ}_{j} {ρ}_{k}} {Q}_{1 / 2} ( {η}_{j} ) {Q}_{1 / 2} ( {η}_{k} )$$

The kernel function can be rapidly evaluated through the use of a hypergeometric series for toroidal functions.

As will be discussed in detail below, the coil-loss model and kernel function can be used in the inversion of coil property measurements according to example embodiments of the present disclosure. For instance, the convolution integral can be discretized over a finite mesh representation of the specimen.

Exemplary Coil Designs for Conductivity Sensing

An exemplary coil design that approximates the coil contemplated by the example quantitative coil-loss model will now be set forth. A coil according to example aspects of the present disclosure can include a plurality of concentric conductive loops arranged in two-planes on a multilayer printed circuit board. The plurality of concentric conductive loops can include a plurality of first concentric conductive loops located within a first plane and a plurality of second concentric conductive loops located in a second plane. The second plane can be spaced apart from the first plane by a plane separation distance. The plane separation distance can be selected such that the coil approximates the single plane coil contemplated in the example quantitative analytical coil-loss model for conductivity sensing disclosed herein.

In addition, the plurality of conductive loops can be connected in series using a plurality of connection traces. The plurality of connection traces can be arranged so that the contribution to the fields generated by the connection traces can be reduced. In this manner, the coil according to example aspects of the present disclosure can exhibit behavior that approximates a plurality of circular loops arranged concentric to one another and located in the same plane.

FIG. 4 depicts an example coil 200 used for magnetic induction conductivity sensing according to exemplary aspects of the present disclosure. As shown, the coil 200 includes ten concentric conductive loops. More particularly, the coil 200 includes five first concentric conductive loops 210 disposed in a first plane and five second concentric conductive loops 220 disposed in a second plane. The first and second concentric conductive loops 210 and 220 can be 1 mm or 0.5 mm copper traces on a multilayer printed circuit board. In one example implementation, the radii of the five concentric conductive loops in either plane are set at about 4 mm, 8 mm, 12 mm, 16 mm, and 20 mm respectively. Another exemplary implementation can include four layers of conductive loops, each layer including two loops, an inner loop with a radius that can be 8 mm and an outer loop having a radius of 12 mm. Of course, it is to be appreciated that other suitable numbers of coil loops and layers, dimensions, and spacing can be used without deviating from the scope of the present disclosure as long as the layer spacing remains significantly smaller than the loop radius.

As shown, each of the plurality of first concentric conductive loops 210 is disposed such that it overlaps one of the plurality of second concentric conductive loops 220. In addition, the first concentric conductive loops 210 and the second concentric conductive loops 220 can be separated by a plane separation distance. The plane separation distance can be selected such that the coil 200 approximates a single plane of concentric loops as contemplated by the quantitative analytical coil-loss model. For instance, the plane separation distance can be in the range of about 0.2 mm to about 0.7 mm, such as about 0.5 mm.

The plurality of first conductive loops 210 can include a first innermost conductive loop 214. The first innermost conductive loop 214 can be coupled to an RF energy source. The plurality of second conductive loops 220 can include a second innermost conductive loop 224. The second innermost conductive loop 224 can be coupled to a reference node (e.g. a ground node or common node).

The coil further includes a plurality of connection traces 230 that are used to connect the first concentric conductive loops 210 and the second concentric conductive loops 220 in series. More particularly, the connection traces 230 couple the plurality of first concentric conductive loops 210 in series with one another and can couple the plurality of second concentric conductive loops 220 in series with one another. The connection traces 230 can also include a connection trace 235 that couples the outermost first concentric conductive loop 212 with the outermost second concentric conductive loop 214 in series.

As shown in more detail in FIG. 5, the connection traces 230 can be arranged such that fields emanating from the connection traces oppose each other. More particularly, the connection traces 230 can be radially aligned such that a current flow of one of the plurality of connection traces located in the first plane is opposite to a current flow of one of the plurality of connection traces located in the second plane. For instance, referring to FIG. 5, connection trace 232 arranged in the first plane can be nearly radially aligned with connection trace 234 in the second plane. A current flowing in connection trace 232 can be opposite to the current flowing in connection trace 234 such that fields generated by the connection traces 232 and 234 oppose or cancel each other.

As further illustrated in FIG. 5, each of the plurality of first conductive loops 210 and the second conductive loops 220 can include a gap 240 to facilitate connection of the conductive loops using the connection traces 230. The gap can be in the range of about 0.2 mm to about 0.7 mm, such as about 0.5 mm.

The gaps 240 can be offset from one another to facilitate connection of the plurality of concentric conductive loops 210 and 220 in series. For instance, a gap associated with one of the plurality of first concentric conductive loops 210 can be offset from a gap associated with another of the plurality of first concentric conductive loops 210. Similarly, a gap associated with one of the plurality of second concentric conductive loops 220 can be offset from a gap associated with another of the plurality of second concentric conductive loops 220. A gap associated with one of the first concentric conductive loops 210 can also be offset from a gap associated with one of the plurality of second concentric conductive loops 220. Gaps that are offset may not be along the same axis associated with the coil 200.

The coil 200 of FIGS. 4 and 5 can provide a good approximation of the coil contemplated by the quantitative analytical coil-loss model for magnetic induction conductivity sensing. In this way, coil property measurements using the coil 200 can be used to generate conductivity values of fluid and other potential contents within a fluid vessel 110.

Exemplary Circuit for Obtaining Coil Property Measurements

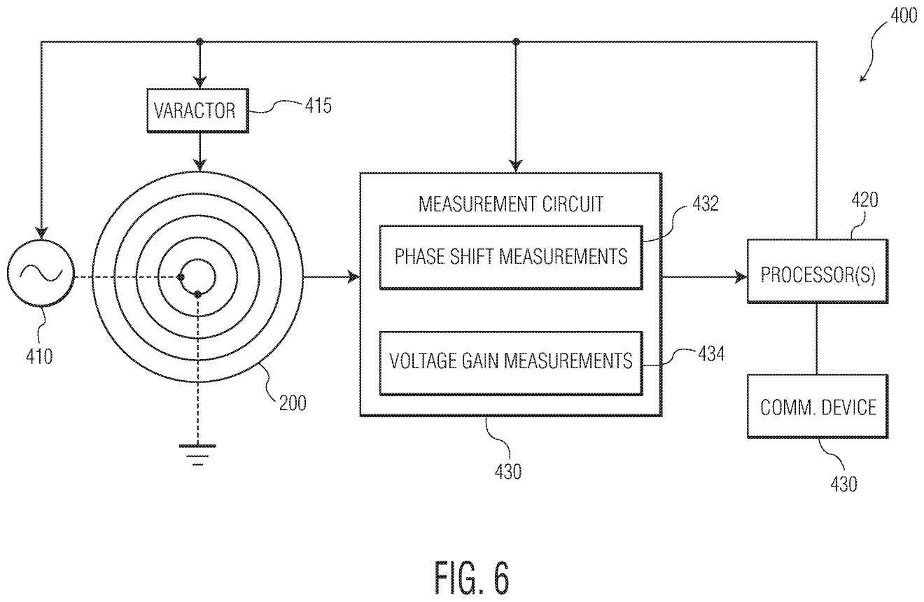

FIG. 6 depicts a diagram of an exemplary circuit 400 that can be used to obtain coil property measurements using the coil 200 of FIGS. 4 and 5. As shown, the circuit 400 of FIG. 6 includes an RF energy source 410 (e.g. an oscillator circuit) configured to energize the coil 200 with RF energy. The RF energy source 410 can be a fixed frequency crystal oscillator configured to apply RF energy at a fixed frequency to the coil 200. The fixed frequency can be, for instance, about 12.5 MHz. In one example embodiment, the RF energy source 410 can be coupled to an innermost concentric conductive loop of the plurality of first concentric conductive loops of the coil 200. The innermost concentric conductive loop of the plurality of second concentric conductive loops of the coil 200 can be coupled to a reference node (e.g. common or ground).

The circuit 400 can include one or more processors 420 to control various aspects of the circuit 400 as well as to process information obtained by the circuit 400 (e.g. information obtained by measurement circuit 430). The one or more processors 420 can include any suitable processing device, such as digital signal processor, microprocessor, microcontroller, integrated circuit or other suitable processing device.

The one or more processors 420 can be configured to control various components of the circuit 400 in order to capture a coil loss measurement using the coil 200. For instance, the one or more processors 420 can control a varactor 415 coupled in parallel with the coil 200 so as to drive the coil 200 to resonance or near resonance when the coil 200 is positioned adjacent a vessel 110 for a coil property measurement. The one or more processors 420 can also control the measurement circuit 430 to obtain a coil property measurement when the coil 200 is positioned adjacent the vessel 110.

The measurement circuit 430 can be configured to obtain coil property measurements with the coil 200. The coil property measurements can be indicative of coil losses of the coil 200 resulting from eddy currents induced in the fluid or other contents within the vessel 110. In one implementation, the measurement circuit 430 can be configured to measure the real part of admittance changes of the coil 200. The real part of admittance changes of the coil 200 can be converted to real part of impedance changes of the coil 200 as the inverse of admittance for purposes of the analytical coil-loss model discussed above.

The admittance of the coil 200 can be measured in a variety of ways. In one embodiment, the measurement circuit 430 measures the admittance using a phase shift measurement circuit 432 and a voltage gain measurement circuit 434. For instance, the measurement circuit 430 can include an AD8302 phase and gain detector from Analog Devices. The phase shift measurement circuit 432 can measure the phase shift between current and voltage associated with the coil 200. The voltage gain measurement circuit 434 can measure the ratio of the voltage across the coil 200 with a voltage of a sense resistor coupled in series with the coil 200. The admittance of the coil 200 can be derived (e.g., by the one or more processors 420) based on the phase and gain of the coil 200 as obtained by the measurement circuit 430.

Once the coil property measurements have been obtained, the one or more processors 420 can store the coil property measurements, for instance, in a memory device. The one or more processors 420 can also communicate the coil property measurements to one or more remote devices for processing to convert the coil property measurements to conductivity values of the fluid or other contents within the vessel 110. Communication device 440 can include any suitable interface or device for communicating the conductivity values or further information to a remote device over wired or wireless connections and/or networks.

Methods of determining fluid characteristics within a vessel utilizing a sensor system 100 as described above will now be discussed. Importantly, the sensor system as described above can determine fluid characteristics in a non-invasive manner. In other words, the methods described herein provide methods of determining fluid characteristics without disrupting the fluid or other contents within the vessel 110 containing and/or transferring the fluid. The methods described herein can function for vessels 110 for which at least a portion of which are non-conductive. As examples, non-conductive vessels 110, or portions of which that are non-conductive, could be comprised of glass, polyvinylchloride (PVC), polycarbonate, rubber, etc. In some embodiments, a majority of the vessel 110 can be non-conductive. In other embodiments, substantially all of the vessel 110 is non-conductive.

FIG. 7 illustrates the coil device 120 including a single coil 125 described above being positioned near or at an external surface 111 of the vessel 110. Preferably, the coil device 120 is centered on and touching the external surface 111 of the vessel 110 such that the coil plane of the single coil 125 is parallel to the longitudinal axis L of the vessel 110 and the coil axis A intersects the longitudinal axis L of the vessel 110. In circumstances where the vessel 110 is not substantially comprised of non-conductive material, the coil device 120 should be positioned near an external surface 11 of the vessel at the portion of the vessel 110 that is non-conductive.

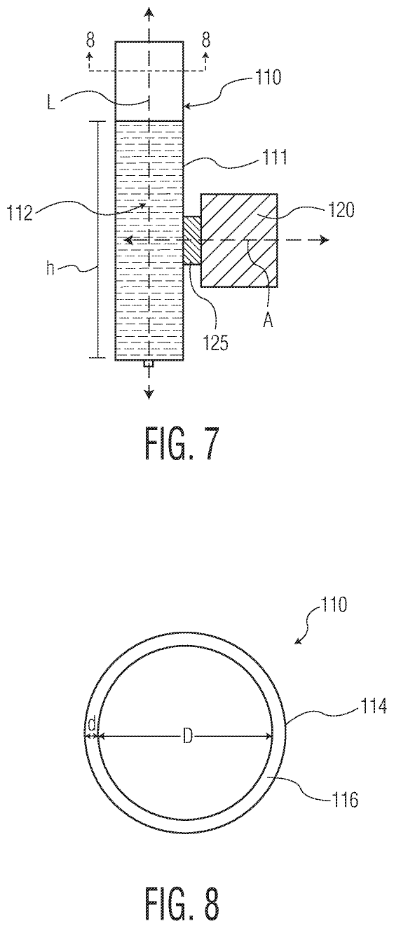

Preferably, before the coil device 120 can be operated as described above, the sensor system 100 can be calibrated to the vessel 110. Specifically, the sensor system 100 can be calibrated to provide a column calibration factor. The column calibration factor is dependent upon a cross-sectional area of the vessel 110 and a wall thickness d of the vessel 110. For example, FIG. 8 illustrates a cross-sectional view of the vessel 110 of FIG. 7, in which the vessel 110 is circular in cross-section with an internal diameter D and a substantially uniform wall thickness d. Of course, methods disclosed herein can be utilized on vessels 110 that are not circular in cross-section and calibration techniques can take into account the cross-sectional area by calculations known to one of ordinary skill in the art. Additionally, the methods described herein can be utilized on vessels 110 that do not have substantially uniform wall thickness d, as long as the wall thickness d is known at the location(s) in which the coil device 120 will be generating coil loss measurements.

To develop the column calibration factor, a series of experiments were conducted involving vessels of known internal diameter D and known wall thickness d and that had fluid of sodium chloride of differing molarity. The vessels 110 were glass columns filled to a height h of approximately 10.0 cm (as illustrated in FIG. 7), with sodium chloride fluid of 1.0 M. The coil device 120 was placed approximately in the center of the fluid height h and the coil loss within the coil device was measured as described above for the sensor system 100. Table 1 below shows the diameter D and the wall thickness of the vessels 110 that were utilized in the experiments as well as the measured coil loss. (cm²). As shown in Table 1, the magnitude of the coil loss is a function of the internal cross-sectional area of the vessel 110.

TABLE 1
Measurements related to three experimental
vessels containing 1.0M sodium chloride

| Vessel Internal | Vessel Wall | Internal Cross-sectional | Measured |
|---|---|---|---|
| Diameter D | Thickness d | Area of Vessel | Coil Loss |
| (cm) | (cm) | (cm²) | (ohms) |
| 1.5 | 0.10 | 1.77 | 0.1 |
| 2.5 | 0.15 | 4.91 | 0.3 |
| 5.0 | 0.24 | 19.63 | 1.08 |

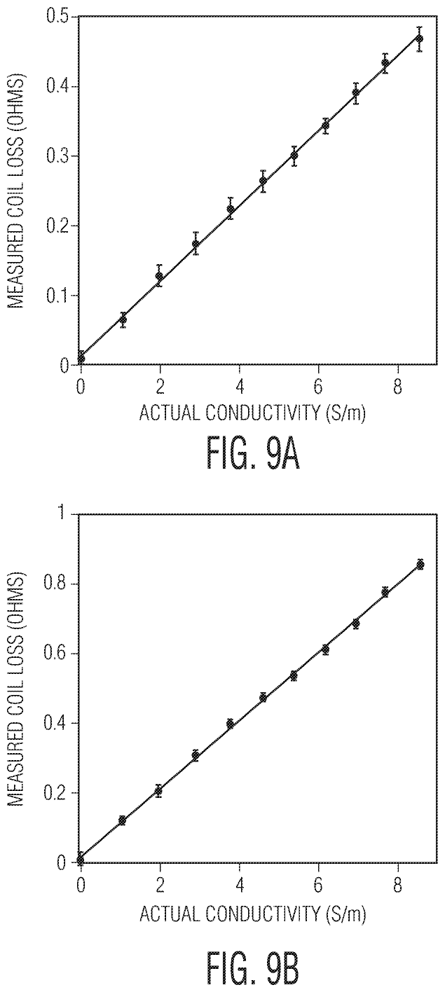

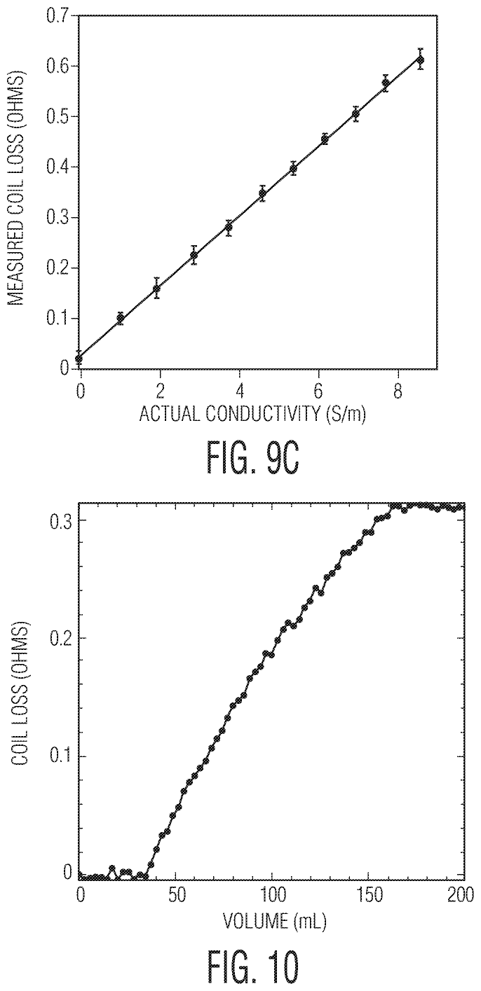

In further experimentation, as illustrated in FIGS. 9A-9C, it was discovered that the coil loss measurements of the sensor system were nearly exactly proportional to the solution conductivity. To test this relationship, three different fluid vessels of various internal diameters D and materials were tested with sodium chloride solutions that included molarity gradients of 0.0M to 1.0M. These experiments involved measuring the actual conductivity of each sodium chloride solution using a Mettler Toledo Seven2Go conductivity meter and correspondingly measuring the coil loss at the same points by moving the conductivity meter and coil device 120 to different heights of the sodium chloride solution (i.e., different molarities within the sodium chloride solutions). In each of the experiments, three sets of data were collected and the mean value of the three readings was plotted, with error bars depicting the standard deviation of the three readings.

For example, FIG. 9A illustrates a graph depicting the actual conductivity of a sodium chloride solution having a molarity gradient ranging between 0.0M and 1.0M in relation to measured coil loss taken at several different points within the sodium chloride solution within a glass vessel 110 having an internal diameter D of 2.5 cm. As illustrated in FIG. 9A, the coil loss as measured by the sensor system 100 and the actual conductivity display a linear relationship having a correlation coefficient of 0.9994. The standard deviation was about the mean for the values used to generate FIG. 9A was only about 2%, indicating the accuracy to which measured coil loss can correlate to conductivity.

FIG. 9B illustrates a similar graph to FIG. 9A depicting the actual conductivity of a sodium chloride solution having a molarity gradient ranging between 0.0M and 1.0M in relation to measured coil loss taken at several different points within the sodium chloride solution within a glass vessel 110 having an internal diameter D of 5.0 cm. Again, the coil loss to actual conductivity was nearly perfectly linear, with a correlation coefficient of 0.9995. As shown in FIG. 9B in comparison to FIG. 9A, it appears that the larger the internal diameter, the decrease in variance present for coil loss measurements using the sensor system 100. As a result, coil diameter can be optimized for a particular internal diameter D and wall thickness D of a vessel to further improve readings. Preferably, the coil diameter of the magnetic induction conductivity sensor is approximately equal to or less than the internal dimension of the vessel 110 (internal diameter D of the vessel 110 if the vessel 110 is a circular pipe), because such a configuration reduces the amount of sensing of air surrounding the vessel 110 which can create a larger dielectric value.

FIG. 9C illustrates similar results to FIGS. 9A and 9, except the sodium chloride solution fluid 112 was contained within a PVC pipe having an internal diameter D of 4.0 cm. This shows that the sensor system 100 can be used in a variety of non-conductive materials that may form a portion or more of a vessel 110. In FIG. 9C, the correlation coefficient between the measured coil loss to actual conductivity was 0.9997.

As shown from the experimentation above, the sensor system 100 could effectively measure coil loss in a way that correlated in a linear fashion to conductivity values. As such, a column calibration factor based on the cross-sectional area of the vessel 110 and the wall thickness d of the vessel 110 can be utilized to provide part of the analytical model 150 mentioned above. By providing a column calibration factor, the sensor system 100 can generate coil loss measurements and convert the coil loss measurements into corresponding conductivity values for the fluid 112 within the vessel 110.

The column calibration factor that converts a coil loss measurement to a conductivity value can be implemented into the analytical coil-loss model 150 for the sensor system 100. If conductivity is assumed to be constant within a portion of the vessel 110 falling within the coil's field of view, then the coil loss equation can be simplified to:

δZ(\vec{c})=σ∫G(\vec{r}_{c})dxdydz

The integral is computed over a liquid region, contained within the vessel 110, which extends along its axis L to about five coil diameters. This ensures that all liquid experiencing the coil's electromagnetic field is included in the calculation. Since conductivity is the only unknown in the equation, conductivity is computed as:

σ=δZ(\vec{c})×C.F.

A calibration factor is then defined as:

$$C . F . = \frac{1}{\int G ( {\vec{r}}_{c} ) dxdydz}$$

A calibration factor depends on coil geometry through the function G(\vec{r_{c}}), and vessel 110 dimensions, which are known, and thus, there are no unspecified parameters. The argument \vec{r_{c}} is the vector locating any point in the liquid, relative to the coil center. As noted above, it is preferred to have the coil diameter be equal or less than the vessel 110 internal diameter D to improve accuracy. The conductivity values of the fluid 112 within the vessel 110 can be converted directly from coil loss measurements, such as by the processor 142 forming part of the computing system 140.

In further experimentation it was discovered that fluid conductivity gradients could surprisingly be captured in real time as fluid was flowing within a vessel 110 utilizing the sensor system 100 described above. Doing so provides further applications in which the sensor system 100 could be utilized to measure fluid conductivity values, such as, but not limited to, monitoring salt changes in pipes in scientific or industrial settings. As one example, a standard feature of protein purification is to elute proteins from ion exchange resins by applying linear or curvilinear gradients into the flow. Traditionally, these gradients were monitored via flow cells that is placed at the end of the column or a regular conductivity meter that is used to measure the individual fractions that have been collected from the column. In industrial settings, solution conductivity is measured with an in-flow dwelling device or samples are collected periodically from the pipe or column and measured with a conductivity meter. In some instances, a solenoid can be used to detect changes in current caused by conductivity differences. In all cases, it is impossible to directly assess the concentration of salt in the pipe or column flow and one must interact with the solution under flow.

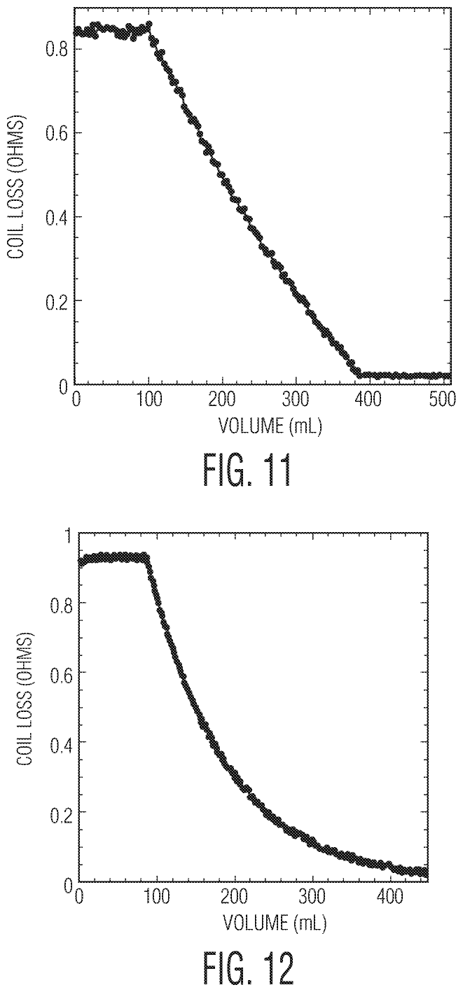

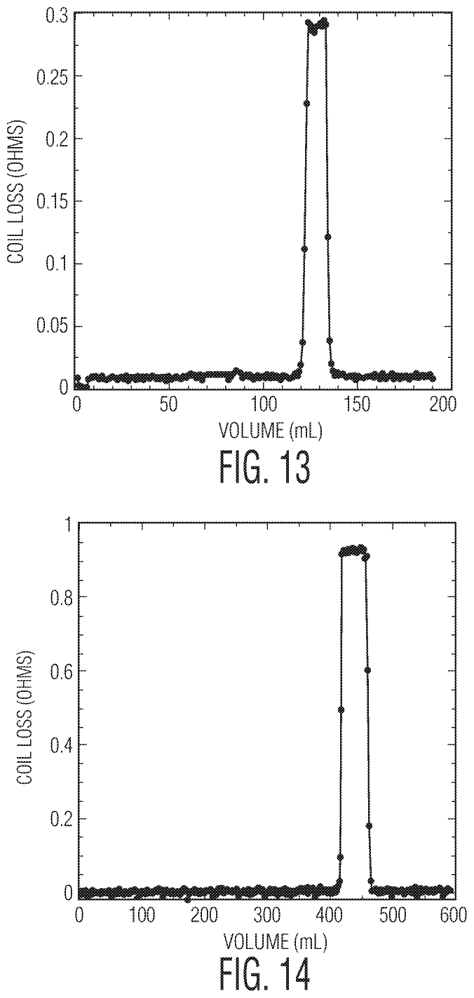

However, the sensor system 100 described above provides a robust platform that can relate and convert measured coil loss to the actual salt concentration (via the conductivity) for any pattern of gradient flow in a non-invasive manner. FIGS. 10-14 illustrate the measured coil loss through three different sodium chloride gradients as solutions were flowing through a vessel 110. There are three kinds of conductivity changes associated with a flowing column of fluid 112. First, the conductivity can linearly vary from low to high values or high to low values. FIGS. 10 and 11, as will be described further below, illustrate the sensor system 100 measuring such linear conductivity gradients. Secondly, the conductivity can vary in a nonlinear fashion; meaning the conductivity vs volume plot shows a convex or concave character. FIG. 12 illustrates one example of such a conductivity gradient. And thirdly, the conductivity can abruptly change (again high to low or low to high values) and return to its previous value. FIGS. 13 and 14 illustrate abrupt changes in conductivity gradients.

For each of the experiments measuring sodium chloride gradients illustrated in FIGS. 10-14, a glass column was filled with BioGel P50 resin (Fisher Scientific). For the experiments illustrated by FIGS. 10 and 14, the glass column or vessel 110 had an internal diameter D of 2.5 cm (4.91 cm²) and was filled to a height h of 40 cm, for an approximate volume of 200 mL. For the experiments illustrated by FIGS. 11-13, the glass column or vessel 110 had an internal diameter D of 5.0 cm (19.62 cm²) and was filled to a height of 30 cm, for an approximate volume of 400 mL. As known by one of ordinary skill in the art, the salt gradients of known configuration were applied to a chromatography column using a gradient maker.

For the experiment illustrated by FIG. 10, a linear 0.0M to 1.0M sodium chloride gradient was hand formed and the flow rate was maintained at 1.0 mL/min. FIG. 10 illustrates that the coil loss measured by the sensor system 100 was measured in a linear fashion as the sodium chloride solution flowed through the vessel 110.

For the experiment illustrated by FIG. 11, a linear 1.0M to 0.0M sodium chloride gradient was hand formed and the flow rate was maintained at 4.0 mL/min. Similar to FIG. 10, FIG. 11 illustrates that the coil loss measured by the sensor system 100 was measured in a linear fashion as the sodium chloride solution flowed through the vessel 110, but started at a higher coil loss and decreased in a linear fashion due to the inverted sodium chloride gradient configured for the experiment for FIG. 11.

For the experiment illustrated by FIG. 12, a concave 1.0M to 0.0M sodium chloride gradient was hand formed and the flow rate was maintained at 4.0 mL/min. As illustrated in FIG. 12, the sensor system 100 measured the coil loss in concave fashion, matching the concave conductivity gradient.

As noted above, FIGS. 13 and 14 illustrate experiments on measuring conductivity gradients that had an abrupt change, but then returned to previous values. For FIG. 13, a 20 mL pulse of 1.0M sodium chloride was applied to the BioGel P50 column that otherwise was filled at 0.0M sodium chloride buffer solution. The flow rate for the experiment illustrated in FIG. 13 was maintained at 1.0 mL/min. As depicted in FIG. 13, the sensor system 100 was capable of accurately detecting and measuring the 20 mL pulse of the 1.0M sodium chloride in the 0.0M sodium chloride buffer solution column.

FIG. 14 illustrates a similar abrupt change in conductivity gradient experiment as FIG. 13. For the experiment illustrated in FIG. 14, a 50 mL pulse of 1.0M sodium chloride was applied to the BioGel P50 column that otherwise had a 0.0M sodium chloride buffer solution. The flow rate for the experiment illustrated in FIG. 14 was maintained at 4.0 mL/min. As shown in FIG. 14, the sensor system again was capable of accurately detecting and measuring the 50 mL pulse of the 1.0M sodium chloride in the BioGel P50 column that otherwise had a 0.0M sodium chloride buffer solution.

As can be seen from the experiments illustrated in FIGS. 10-14, the sensor system 100 is capable of accurately detecting various fluid gradients in real-time in a fluid 112 within a vessel 110 in a non-invasive manner by measuring the coil loss with the coil device 120 as the fluid flows through the vessel 110. As described above, the analytical coil-loss model 150 can be configured to convert the plurality of coil loss measurements to provide a plurality of conductivity values of the fluid 112 within the vessel 110. In doing so, the sensor system 100 can determine a fluid conductivity gradient within the vessel 110.

The sensor system 100 can also be utilized in a mobile manner to detect fluid characteristics in vessel 110 through a specified length of the vessel 110. Not only does this provide mobility for selecting a specific position of a vessel 110 at which to monitor the fluid 112, this mobility can also provide advantages for determining various characteristics of the fluid 112.

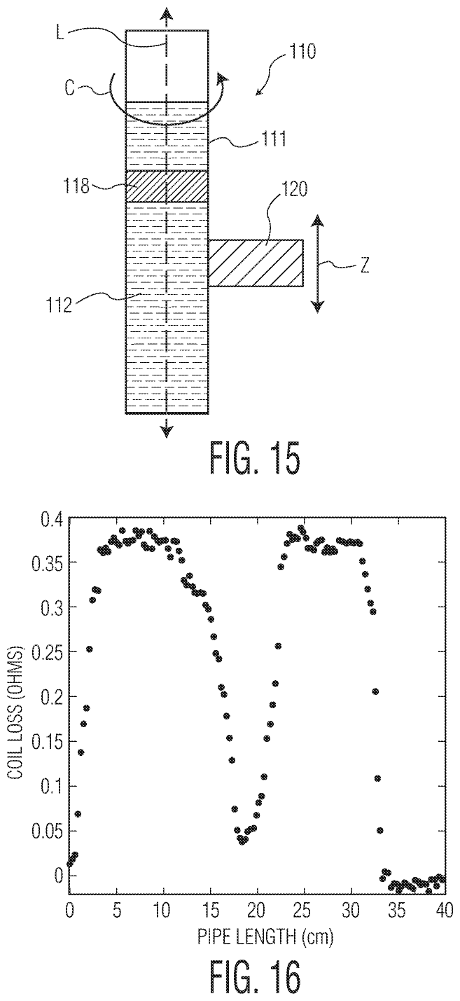

As an example, the mobility of the sensor system 100 to move along the length of the vessel 110 can aid in the detection for the presence of and location of an obstruction 118 within fluid 112 within a vessel 110. Turning to FIG. 15, a coil device 120 as described above is placed near an external surface 111 of the vessel 110 including fluid 112. The coil device 120 can be moved with respect to the vessel 110 to search for an obstruction 118, whether it be a partial obstruction or a complete obstruction. As illustrated in FIG. 15, the coil device 120 of sensor system 100 can move with respect to the vessel 110 in a direction Z generally parallel to a longitudinal axis L of the vessel 110. Additionally and/or alternatively, the coil device 120 of sensor system 100 can move in a circumferential direction C around the vessel 110 with respect to the longitudinal axis L of the vessel 110.

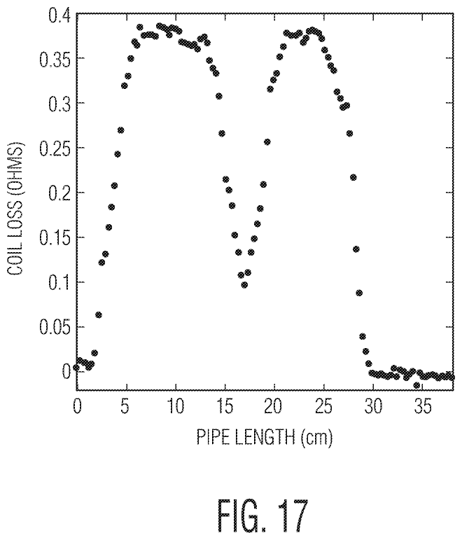

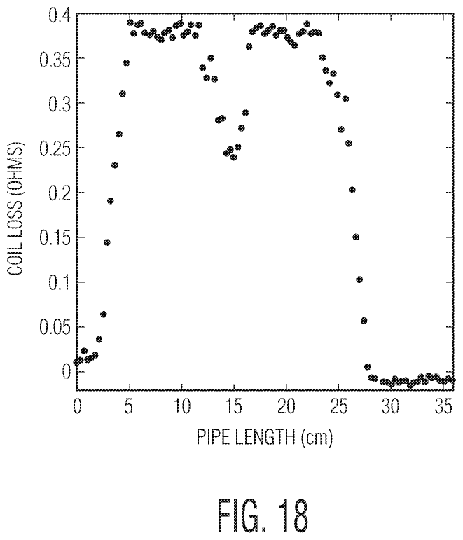

In experimental set-ups such as that shown in FIG. 15, three experiments were run with the sensor system 100 to detect obstructions 118 within a vessel 110. FIG. 16 depicts the results of the detection for the presence of and location of a 6 cm long obstruction 118 that was placed within a 40 cm long vessel 110 filled with a 1.0M sodium chloride solution. FIG. 17 illustrates the results of the detection for the presence of and location of a 4 cm long obstruction 118 that was placed within a fluid solution in a 38 cm long vessel 110 filed with a 1.0M sodium chloride solution. FIG. 18 illustrates the results of the detection for the presence of and location of a 2 cm long obstruction 118 that was placed within a fluid solution in a 36 cm long vessel 110 filed with a 1.0M sodium chloride solution. In each of FIGS. 16-18, measured coil loss increases until the coil device 120 encounters the start of the vessel 110, obtains a maximum loss as the coil device 120 is fully surrounded by the vessel 110, decreases as the coil device 120 encounters and moves across the obstruction 118, increases again as the coil device encounters the fluid 112 beyond the obstruction 118, and finally decreases as the coil device 120 passes the end of the vessel 110.

From these results, the sensor system 100 demonstrates that it can determine the presence and the location of an obstruction 118 within the vessel 110 due to a substantial change in a progression of the plurality of coil loss measurements that are generated by the coil device 120 from an expected value of coil loss. For example, in the experiment illustrated in FIG. 18 described above an expected coil loss for the coil device can be configured to be about 0.37 ohms. The analytical coil-loss model 150 described above can then be configured to define a substantial change in a progression of the plurality of coil loss measurements as a change in which at least two adjacent coil loss measurements are greater than or less than 10% of the expected coil loss.

In a further embodiment, the sensor system 100 could be further configured to be calibrated to provide a column calibration factor in the analytical coil-loss model 150 based upon a cross-sectional area of the vessel 110 and a wall thickness d of the vessel 110 as noted above. The sensor system 100 could be configured to convert the plurality of coil loss measurements utilizing the single coil magnetic induction conductivity sensor to a plurality of conductivity values of the fluid 112 within the vessel 110 via the analytical coil-loss model 150 described above. In such a configuration, the sensor system can further be configured to determine the presence and location of the obstruction 118 based on the converted conductivity values of the fluid 112, not merely the coil loss measurements. In a similar fashion to that as described above with respect to the change in a progression of coil loss measurements, the analytical coil-loss model 150 could be configured to have an expected conductivity value and determine the presence and the location of the obstruction 118 in the vessel 110 due to a substantial change in a progression of the plurality of conductivity values of the fluid 112 from the expected conductivity value.

In some embodiments, the sensor system 100 can be configured to include a computing system 140 that can include an alarm. The alarm can be configured to provide some form of an alert (e.g., auditory, visual, tactile, etc.) to an operator of the system 100 to notify them of an obstruction 118 in the fluid 112 in a vessel 110.

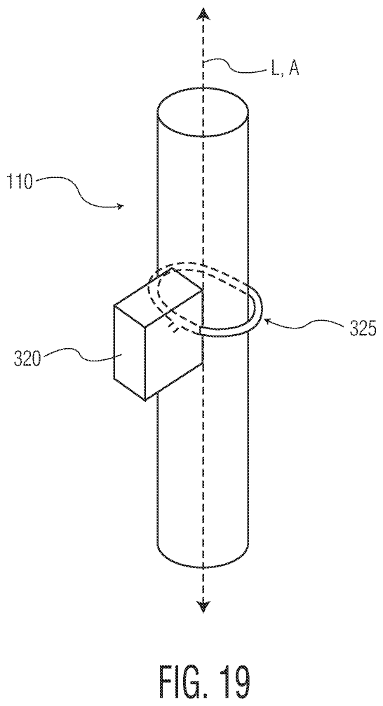

FIG. 19 illustrates an alternative embodiment of a coil device 320 for a sensor system that is configured to measure coil loss and/or conductivity values as described above. The coil device 320 includes a single coil 325 that includes a diameter greater than the external dimensions of the vessel 110 such that the single coil 325 wraps around the vessel 110. As illustrated in FIG. 19, the longitudinal axis A of the single coil 325 can be substantially co-linear with the longitudinal axis L of the vessel 110. The single coil 325 can be configured with various numbers of loops and layers as described above as long as the layer spacing remains significantly smaller than the loop radius. A benefit to this alternative coil 325 arrangement is that the coil 325 can be specifically sized for a vessel 110 and by having the longitudinal axis A of the single coil 325 be substantially co-linear with the longitudinal axis L of the vessel 110, the coil loss measurements can be more accurate due to less sensing of air around the vessel 110. This alternative configuration may be preferable where the coil device 320 is intended to be stationary and can be mounted on or near the vessel 110 in a particular location.

### EMBODIMENTS

### Embodiment 1

A non-invasive method of determining a fluid characteristic within a vessel, the vessel comprising at least a portion that is non-conductive, the method comprising: providing a sensor system comprising: a single coil magnetic induction conductivity sensor; a processor; and a computing system, the processor and the computing system being configured to run an analytical coil-loss model; calibrating the sensor system to the vessel to provide a column calibration factor in the analytical coil-loss model, the column calibration factor being dependent upon a cross-sectional area of the vessel and a wall thickness of the vessel; positioning the single coil magnetic induction conductivity sensor near an external surface of the vessel at the at least a portion of the vessel that is non-conductive; generating a coil loss measurement utilizing the single coil magnetic induction conductivity sensor; and converting the coil loss measurement to a conductivity value of the fluid within the vessel.

### Embodiment 2

The method of embodiment 1, the method further comprising: generating a plurality of coil loss measurements utilizing the single coil magnetic induction conductivity sensor; and converting the plurality of coil loss measurements utilizing the single coil magnetic induction conductivity sensor to a plurality of conductivity values of the fluid within the vessel.

### Embodiment 3

The method of embodiment 2, wherein the fluid flows in the vessel, and wherein converting the plurality of coil loss measurements utilizing the single coil magnetic induction conductivity sensor to a plurality of conductivity values of the fluid as it flows through the vessel provides a conductivity gradient of the fluid within the vessel.

### Embodiment 4

The method of any one of the preceding embodiments, wherein the single coil magnetic induction conductivity sensor is kept generally stationary near the external surface of the vessel.

### Embodiment 5

The method of any one of embodiments 1-3, further comprising: moving the single coil magnetic induction conductivity sensor with respect to the vessel while generating a plurality of coil loss measurements utilizing the single coil magnetic induction conductivity sensor.

### Embodiment 6

The method of embodiment 5, wherein the single coil magnetic induction conductivity sensor is moved generally parallel to a longitudinal axis of the vessel.

### Embodiment 7

The method of embodiment 5, wherein the single coil magnetic induction conductivity sensor is moved generally circumferential to a longitudinal axis of the vessel.

### Embodiment 8

The method of embodiment 5, wherein moving the single coil magnetic induction conductivity sensor with respect to the vessel while generating a plurality of coil loss measurements utilizing the single coil magnetic induction conductivity sensor is adapted to determine a presence and a location of an obstruction to fluid flow within the vessel.

### Embodiment 9

The method of embodiment 8, wherein the obstruction partially obstructs fluid flow in the vessel.

### Embodiment 10

The method of embodiment 8, wherein the obstruction is a complete obstruction preventing fluid flow in the fluid vessel.

### Embodiment 11

The method of any one of the preceding embodiments, wherein a majority of the vessel is non-conductive.

### Embodiment 12

The method of any one of the preceding embodiments, wherein the single coil conductivity sensor wraps around the vessel such that a longitudinal axis of the single coil conductivity sensor is substantially co-linear with a longitudinal axis of the vessel.

### Embodiment 13

A non-invasive method of determining a presence and a location of an obstruction to fluid flow within a vessel, the vessel comprising at least a portion that is non-conductive, the method comprising: providing a sensor system comprising: a single coil magnetic induction conductivity sensor; a processor; and a computing system, the processor and the computing system being configured to run an analytical coil-loss model; positioning the single coil magnetic induction conductivity sensor near an external surface of the vessel at the at least a portion of the vessel that is non-conductive; moving the single coil magnetic induction conductivity sensor with respect to the vessel; generating a plurality of coil loss measurements utilizing the single coil magnetic induction conductivity sensor; analyzing the plurality of coil loss measurements; and determining the presence and the location of the obstruction in the vessel due to a substantial change in a progression of the plurality of coil loss measurements.

### Embodiment 14

The method of embodiment 13, further comprising: calibrating the sensor system to the vessel to provide a column calibration factor in the analytical coil-loss model, the column calibration factor being dependent upon a cross-sectional area of the vessel and a wall thickness of the vessel; and converting the plurality of coil loss measurements utilizing the single coil magnetic induction conductivity sensor to a plurality of conductivity values of the fluid within the vessel; and wherein determining the presence and the location of the obstruction in the vessel is due to a substantial change in a progression of the plurality of conductivity values of the fluid.

### Embodiment 15

The method of embodiment 13 or 14, wherein the single coil magnetic induction conductivity sensor is moved generally parallel to a longitudinal axis of the vessel.

### Embodiment 16

The method of embodiment 13 or 14, wherein the single coil magnetic induction conductivity sensor is moved generally circumferential to a longitudinal axis of the vessel.

### Embodiment 17

A non-invasive method of determining a fluid conductivity gradient within a vessel, the vessel comprising at least a portion that is non-conductive, the method comprising: providing a sensor system comprising: a single coil magnetic induction conductivity sensor; a processor; and a computing system, the processor and the computing system being configured to run an analytical coil-loss model; calibrating the sensor system to the vessel to provide a column calibration factor in the analytical coil-loss model, the column calibration factor being dependent upon a cross-sectional area of the vessel and a wall thickness of the vessel; positioning the single coil magnetic induction conductivity sensor near an external surface of the vessel at the at least a portion of the vessel that is non-conductive; generating a plurality of coil loss measurements utilizing the single coil magnetic induction conductivity sensor as the fluid flows within the vessel; and converting the plurality of coil loss measurements to a plurality of conductivity values of the fluid within the non-conductive vessel to determine the fluid conductivity gradient within the vessel.

### Embodiment 18

The method of embodiment 17, wherein the single coil magnetic induction conductivity sensor is kept generally stationary near the external surface of the vessel.

### Embodiment 19

A non-invasive system configured for determining a fluid characteristic within a fluid in a vessel, the system comprising: a coil device comprising: a single coil configured to be energized to induce an eddy current; and a processor configured to determine a plurality of coil loss measurements in the single coil; and a computing system configured for receiving the plurality of coil loss measurements, the computing system comprising: a processor; a memory device; and a magnetic induction conductivity sensor module configured to implement an analytical coil-loss model, the analytical coil loss model being calibrated to provide a column calibration factor being dependent upon a cross-sectional area of the vessel and a wall thickness of the vessel, the analytical coil-loss model being configured to define a relationship between the plurality of coil loss measurements obtained by the single coil and a fluid conductivity based on the column calibration factor.

### Embodiment 20

The non-invasive system of embodiment 19, wherein the single coil is configured to wrap around the vessel such that a longitudinal axis of the single coil conductivity sensor is substantially co-linear with a longitudinal axis of the vessel.

When introducing elements of the present disclosure or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. Many modifications and variations of the present disclosure can be made without departing from the spirit and scope thereof. Therefore, the exemplary embodiments described above should not be used to limit the scope of the invention.

What is claimed is:

1. A non-invasive method of determining a fluid characteristic within a vessel, the vessel comprising at least a portion that is non-conductive, the method comprising:
providing a sensor system comprising:
a single coil magnetic induction conductivity sensor;
a processor; and
a computing system, the processor and the computing system being configured to run an analytical coil-loss model;
calibrating the sensor system to the vessel to provide a column calibration factor in the analytical coil-loss model, the column calibration factor being dependent upon a cross-sectional area of the vessel and a wall thickness of the vessel;
positioning the single coil magnetic induction conductivity sensor near an external surface of the vessel at the at least a portion of the vessel that is non-conductive;
generating a coil loss measurement utilizing the single coil magnetic induction conductivity sensor; and
converting the coil loss measurement to a conductivity value of the fluid within the vessel.

2. The method of claim 1, the method further comprising:
generating a plurality of coil loss measurements utilizing the single coil magnetic induction conductivity sensor; and
converting the plurality of coil loss measurements utilizing the single coil magnetic induction conductivity sensor to a plurality of conductivity values of the fluid within the vessel.

3. The method of claim 2, wherein the fluid flows in the vessel, and wherein converting the plurality of coil loss measurements utilizing the single coil magnetic induction conductivity sensor to a plurality of conductivity values of the fluid as it flows through the vessel provides a conductivity gradient of the fluid within the vessel.

4. The method of claim 2, wherein the single coil magnetic induction conductivity sensor is kept generally stationary near the external surface of the vessel.

5. The method of claim 2, further comprising:
moving the single coil magnetic induction conductivity sensor with respect to the vessel while generating a plurality of coil loss measurements utilizing the single coil magnetic induction conductivity sensor.

6. The method of claim 5, wherein the single coil magnetic induction conductivity sensor is moved generally parallel to a longitudinal axis of the vessel.

7. The method of claim 5, wherein the single coil magnetic induction conductivity sensor is moved generally circumferential to a longitudinal axis of the vessel.

8. The method of claim 5, wherein moving the single coil magnetic induction conductivity sensor with respect to the vessel while generating a plurality of coil loss measurements utilizing the single coil magnetic induction conductivity sensor is adapted to determine a presence and a location of an obstruction to fluid flow within the vessel.

9. The method of claim 8, wherein the obstruction partially obstructs fluid flow in the vessel.

10. The method of claim 8, wherein the obstruction is a complete obstruction preventing fluid flow in the fluid vessel.

11. The method of claim 1, wherein a majority of the vessel is non-conductive.

12. The method of claim 1, wherein the single coil conductivity sensor wraps around the vessel such that a longitudinal axis of the single coil conductivity sensor is substantially co-linear with a longitudinal axis of the vessel.

13. A non-invasive method of determining a presence and a location of an obstruction to fluid flow within a vessel, the vessel comprising at least a portion that is non-conductive, the method comprising:
providing a sensor system comprising:
a single coil magnetic induction conductivity sensor;
a processor; and
a computing system, the processor and the computing system being configured to run an analytical coil-loss model;
positioning the single coil magnetic induction conductivity sensor near an external surface of the vessel at the at least a portion of the vessel that is non-conductive;
moving the single coil magnetic induction conductivity sensor with respect to the vessel;
generating a plurality of coil loss measurements utilizing the single coil magnetic induction conductivity sensor;
analyzing the plurality of coil loss measurements; and
determining the presence and the location of the obstruction in the vessel due to a substantial change in a progression of the plurality of coil loss measurements.

14. The method of claim 13, further comprising:
calibrating the sensor system to the vessel to provide a column calibration factor in the analytical coil-loss model, the column calibration factor being dependent upon a cross-sectional area of the vessel and a wall thickness of the vessel; and
converting the plurality of coil loss measurements utilizing the single coil magnetic induction conductivity sensor to a plurality of conductivity values of the fluid within the vessel; and wherein determining the presence and the location of the obstruction in the vessel is due to a substantial change in a progression of the plurality of conductivity values of the fluid.

15. The method of claim 13, wherein the single coil magnetic induction conductivity sensor is moved generally parallel to a longitudinal axis of the vessel.

16. The method of claim 13, wherein the single coil magnetic induction conductivity sensor is moved generally circumferential to a longitudinal axis of the vessel.

17. A non-invasive method of determining a fluid conductivity gradient within a vessel, the vessel comprising at least a portion that is non-conductive, the method comprising:
providing a sensor system comprising:
a single coil magnetic induction conductivity sensor;
a processor; and
a computing system, the processor and the computing system being configured to run an analytical coil-loss model;
calibrating the sensor system to the vessel to provide a column calibration factor in the analytical coil-loss model, the column calibration factor being dependent upon a cross-sectional area of the vessel and a wall thickness of the vessel;
positioning the single coil magnetic induction conductivity sensor near an external surface of the vessel at the at least a portion of the vessel that is non-conductive;
generating a plurality of coil loss measurements utilizing the single coil magnetic induction conductivity sensor as the fluid flows within the vessel; and
converting the plurality of coil loss measurements to a plurality of conductivity values of the fluid within the non-conductive vessel to determine the fluid conductivity gradient within the vessel.

18. The method of claim 17, wherein the single coil magnetic induction conductivity sensor is kept generally stationary near the external surface of the vessel.

19. A non-invasive system configured for determining a fluid characteristic within a fluid in a vessel, the system comprising:
a coil device comprising:
a single coil configured to be energized to induce an eddy current; and
a processor configured to determine a plurality of coil loss measurements in the single coil; and
a computing system configured for receiving the plurality of coil loss measurements, the computing system comprising:
a processor;
a memory device; and
a magnetic induction conductivity sensor module configured to implement an analytical coil-loss model, the analytical coil loss model being calibrated to provide a column calibration factor being dependent upon a cross-sectional area of the vessel and a wall thickness of the vessel, the analytical coil-loss model being configured to define a relationship between the plurality of coil loss measurements obtained by the single coil and a fluid conductivity based on the column calibration factor.

20. The non-invasive system of claim 19, wherein the single coil is configured to wrap around the vessel such that a longitudinal axis of the single coil conductivity sensor is substantially co-linear with a longitudinal axis of the vessel.
